(19) United States
(12) Patent Application Publication
(10) Pub. No.: US 2008/0194093 A1
(43) Pub. Date: Aug. 14, 2008

(54) METHOD FOR FABRICATING A NONVOLATILE MEMORY DEVICE

(75) Inventor: Sang-Hyon KWAK, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 12/102,710

(22) Filed: Apr. 14, 2008

(30) Foreign Application Priority Data
Sep. 26, 2006 (KR) 2006-0096478
Feb. 26, 2008 (KR) 2008-0017301

(51) Int. Cl. H01L 21/28

(52) U.S. Cl. 438/594; 257/E21.179

(57) ABSTRACT

A method for forming a nonvolatile memory device includes forming a tunnel insulation layer and a first conductive layer over a substrate. A trench is formed by partially etching the first conductive layer, the tunnel insulation layer and the substrate, thereby forming a resultant structure. An insulation layer is formed over the resultant structure to fill the trench. The insulation layer polished using a slurry including a polisher diluted with deionized water to expose the first conductive layer.

### CROSS-REFERENCE TO RELATED APPLICATIONS

The present invention claims priority to Korean patent application number 2008-0017301, filed on Feb. 26, 2008, which is incorporated by reference in its entirety.

### BACKGROUND OF THE INVENTION

The present invention relates to a method for fabricating a nonvolatile memory device and, more particularly, to a method for fabricating a floating gate of a nonvolatile memory device.

In a NAND type flash memory device, which is a nonvolatile memory device, a plurality of cells are connected in series to form a unit string, thereby highly integrating the device. The NAND type flash memory device has a wide application. For example, the NAND type flash memory device can substitute for a memory stick, an universal serial bus (USB) driver, or a hard disk.

In the NAND flash memory device, an isolation layer and a floating gate are simultaneously formed by performing a self aligned-shallow trench isolation (SA-STI) process. By performing the SA-STI process, the floating gate is formed to have a stack structure. Thus, a surface area of the floating gate is easily controlled, thereby maximizing a coupling ratio. However, since a photolithography process is required, an align margin is affected during an etch process. Therefore, as semiconductor devices become more highly integrated, it becomes more difficult to perform the SA-STI process.

Recently, an advanced self aligned-shallow trench isolation (ASA-STI) process has been introduced to highly integrate semiconductor devices. In the ASA-STI process, since the floating gate is formed with a single layer rather than a stack structure, additional photolithography is not required, unlike in the SA-STI process.

Accordingly, the process can be simplified compared to the SA-STI process. Thus, the ASA-STI process has advantages in highly integrating the semiconductor devices.

However, in the ASA-STI process, dimensions of a dielectric layer, i.e., dimensions of an area which contacts with the floating gate, are determined by an effective field oxide height (EFH), i.e., a distance from an upper surface of an active region located between neighboring floating gates to an upper surface of the dielectric layer. Uniformity of the EFH significantly affects device characteristics. Therefore, if the EFH is not uniform to a certain level in a unit process, the non-uniformity increases as more processes are performed. As a result, device characteristics deteriorate.

### SUMMARY OF THE INVENTION

Embodiments of the present invention are directed to a method for fabricating a nonvolatile memory device.

In accordance with an aspect of the present invention, a method for forming a nonvolatile memory device is provided. The method includes forming a tunnel insulation layer and a first conductive layer over a substrate. A trench is formed by partially etching the first conductive layer, the tunnel insulation layer and the substrate, thereby forming a resultant structure. An insulation layer is formed over the resultant structure to fill the trench. The insulation layer is polished using a slurry including a polisher diluted with deionized water to expose the first conductive layer.

In accordance with another aspect of the present invention, a method for fabricating a nonvolatile memory device is provided. The method includes forming a tunnel insulation layer and a first conductive layer over a substrate. A trench is formed by partially etching the first conductive layer, the tunnel insulation layer, and the substrate, thereby forming a resultant structure. An insulation layer is formed over the resultant structure to fill the trench. The insulation layer is polished using a slurry including an organic polymer to expose the first conductive layer.

### BRIEF DESCRIPTION OF THE DRAWINGS

FIGS. 1A to 1H are cross-sectional views illustrating a method of fabricating a nonvolatile memory device in accordance with an embodiment of the present invention.

### DESCRIPTION OF SPECIFIC EMBODIMENTS

Embodiments of the present invention relate to a method for fabricating a nonvolatile memory device.

Referring to the drawings, the illustrated thickness of layers and regions are exaggerated to facilitate explanation. When a first layer is referred to as being “on” a second layer or “on” a substrate, it could mean that the first layer is formed directly on the second layer or the substrate, or it could also mean that a third layer may exist between the first layer and the substrate. Furthermore, the same or like reference numerals throughout the various embodiments of the present invention represent the same or like elements in different drawings.

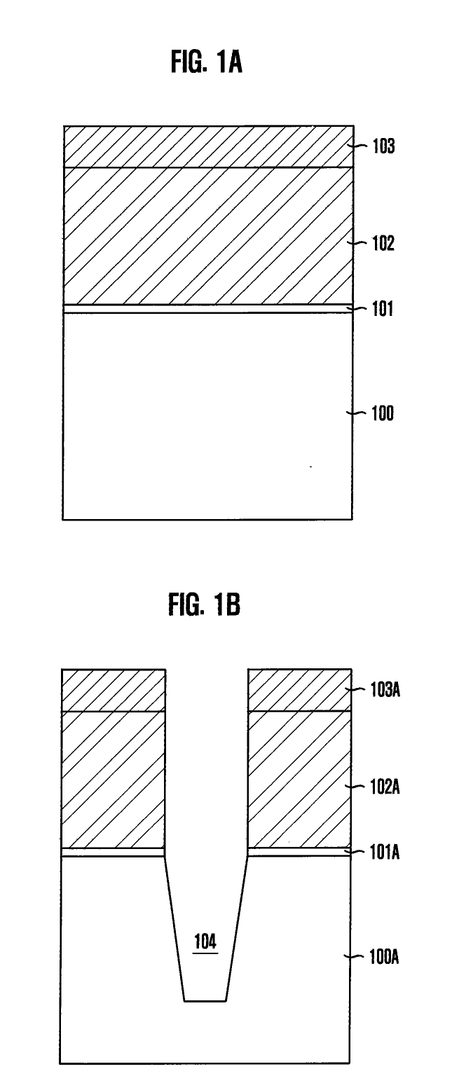

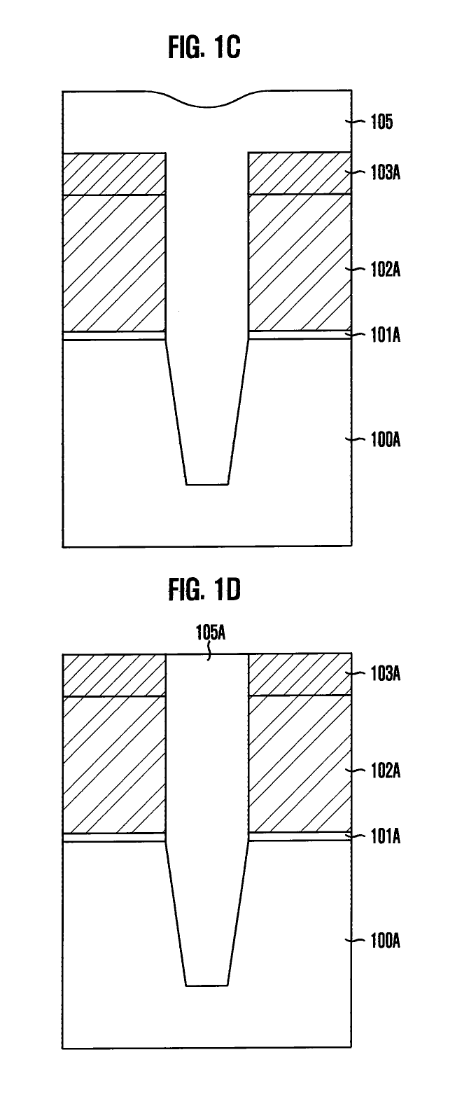

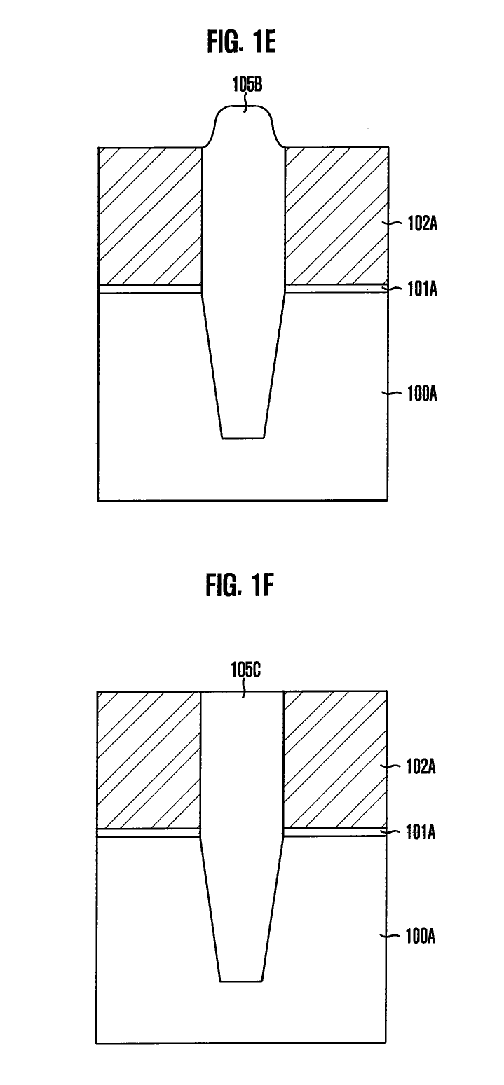

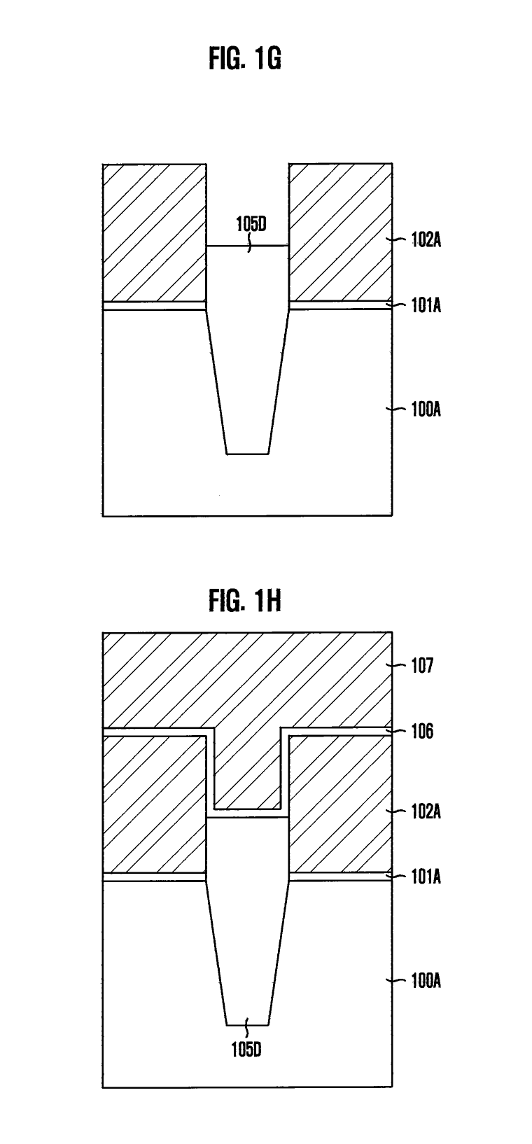

FIGS. 1A to 1H are cross-sectional views illustrating a method of fabricating a nonvolatile memory device in accordance with an embodiment of the present invention. In this embodiment, two neighboring cells arranged in a wordline direction in a memory cell array of a NAND flash memory device are illustrated.

Referring to FIG. 1A, a triple n-type well (not shown) and a p-type well (not shown) are formed in a substrate 100, e.g., a p-type substrate. Ions are implanted into the substrate 100 to adjust a threshold voltage.

A tunnel insulation layer 101 is formed over the substrate 100. The tunnel insulation layer 101 may include an oxide layer, e.g., a silicon oxide (SiO₂) layer.

In accordance with another embodiment of the present invention, after forming the SiO₂ layer on the substrate 100, a thermal process using a nitrogen (N₂) gas can be additionally performed to form a nitride layer at an interface between the SiO₂ layer and the substrate 100, thereby forming the tunnel insulation layer 101 including the SiO₂ layer and the nitride layer. In accordance with still another embodiment of the present invention, the tunnel insulation layer 101 is a metal oxide layer, e.g., an aluminum oxide (AlO₃) layer, a zirconium oxide (ZrO₂) layer, a hafnium oxide (HfO₂) layer, a combination thereof or a stack structure thereof. The AlO₃ layer, the ZrO₂ layer and the HfO₂ layer have a permittivity of more than 3.9. To form the tunnel insulation layer 101, a dry oxidation, a wet oxidation, or an oxidation using a radical ion may be performed. However, it is preferable to perform the dry oxidation or the wet oxidation instead of the oxidation process using the radical ion. The tunnel insulation layer 101 may be formed to have a thickness of approximately 50 Å to approximately 100 Å.

A first conductive layer 102 for a floating gate is formed over the tunnel insulation layer 101. The first conductive layer 102 may include a polycrystalline silicon layer, a transition metal, or a rare earth metal. The first conductive layer 102 may include the polycrystalline silicon layer which has a good interface characteristic with the tunnel insulation layer 101 and a higher etch rate than the metal.

The polycrystalline silicon layer may be formed by a low pressure chemical vapor deposition (LPCVD) method where a silane (SiH₄) gas is used as a source gas and a phosphine (PH₃) gas is used as a doping gas. The transition metal may include iron (Fe), cobalt (Co), tungsten (W), nickel (Ni), palladium (Pd), platinum (Pt), molybdenum (Mo), or titanium (Ti). The rare earth metal may include erbium (Er), ytterbium (Yb), samarium (sm), yttrium (Y), lanthanum (La), cerium (Ce), terbium (Tb), dysprosium (Dy), holmium (Ho), thulium (Tm), or lutetium (Lu).

A hard mask layer 103 is formed over the first conductive layer 102. The hard mask layer 103 may include a material having a higher etch rate than the first conductive layer 102. For instance, when the first conductive layer 102 includes the polycrystalline silicon layer, the hard mask layer 103 includes a nitride layer, e.g. a silicon nitride (Si₃N₄) layer. In accordance with another embodiment of the present invention, the hard mask layer 103 may include a stack structure of a nitride layer, e.g., a Si₃N₄ layer, an oxide layer, e.g., a SiO₂ layer, and an oxide nitride layer, e.g., a SiON layer.

A buffer layer (not shown) may be formed over the first conductive layer 102 before forming the hard mask layer 103. The buffer layer protects the first conductive layer 102 from stress applied when forming the hard mask layer 103. For instance, when the first conductive layer 102 includes the polycrystalline silicon layer, the buffer layer includes a silicon oxide layer formed by performing an oxidation process to minimize surface damage of the polycrystalline silicon layer. When the first conductive layer 102 includes the transition metal or the rare earth metal, the buffer layer is formed with an oxide-based layer such as a silicon oxide layer. The buffer layer may include material other than the oxide-based material. That is, the buffer layer may be formed from material that minimizes loss of the first conductive layer 102 and is formed by a simple process, material that can protect the first conductive layer 102 when forming the hard mask layer 103, or material that can be easily removed by a subsequent process.

Referring to FIG. 1B, a trench 104 is formed by an etch process. The trench 104 is formed to have a width in a cell region that is different from a width in a peripheral region. For instance, the trench 104 may have a greater width in the peripheral region than in the cell region. The cell region indicates a region where a memory cell is formed and the peripheral region indicates a region where driving circuits for driving the memory cell are formed. The driving circuits may include a decoder, a page buffer and other driving circuits.

Hereinafter, the method for forming the trench 104 is described. A hard mask including an amorphous carbon layer or a stack structure of an oxide layer and an amorphous carbon layer is formed on the hard mask layer 103. A SION layer being an anti-reflection layer is formed over the hard mask. The anti-reflection layer and the hard mask are selectively etched using a photoresist pattern to form a hard mask pattern. Portions of the hard mask layer 103, the first conductive layer 102, the tunnel insulation layer 101, and the substrate 100 are etched using the hard mask pattern to form a plurality of trenches 104. A dry etch process is employed to form a vertical profile. For instance, the dry etch process uses a plasma etch apparatus. Hydrogen bromide (HBr), chlorine (Cl₂), or a gas mixture of HBr, Cl₂, and O₂ may be used as an etch gas.

Referring to FIG. 1C, an insulation layer 105 for device isolation is formed over a resultant structure shown in FIG. 1B to fill the trench 104. The insulation layer 105 may include an un-doped silicate glass (USG) layer formed by a high density plasma-chemical vapor deposition (HDP-CVD) method. Alternatively, the insulation layer 105 may include a stack structure of the HDP layer and a spin on dielectric (SOD) layer. The SOD layer may include a polisilazane (PSZ) layer. Other materials formed by a spin coating method can be used as the SOD layer. The insulation layer 105 may include a boron phospho silicate glass (BPSG) layer, a phosphor silicate glass (PSG) layer, a tetra ethyle ortho silicate (TEOS) layer or a stack structure thereof. Materials for the spin coating are shown in Table 1.

TABLE 1

| Deposition Method | Organic-based | Inorganic-based |
|---|---|---|
| SOG | SiLk ™(Dow Chemical, | FOx(Dow Chemical, |
| | k = 2.6) BCB(Dow | HSSQ, k = 3.0) |
| | Chemical, k = 2.7) | HOSP(Honeywell, |
| | FLARE ™(Honeywell, | MSSQ, k = 2.6) |
| | k = 2.8) | JSR(LKD-T200, k = 2.6) |

In Table 1, SiLk™, BCB, FLARE™, FOx, HOSP, JSR are product names. The HSSQ indicates hydrogen sil sesquioxane and the MSSQ indicates methyl sil sesquioxane.

Referring to FIG. 1D, the insulation layer 105 is planarized. The planarization process may be a chemical mechanical polishing (CMP) process or a dry etch process. The dry etch process is an etch-back process.

The CMP process is performed using the etched hard mask layer 103A as a polish stop layer. Specifically, when the insulation layer 105 includes an oxide layer and the hard mask layer 103 includes a nitride layer, the CMP process is performed under a condition that an etch ratio of the oxide layer to the nitride layer is more than approximately 50:1 and, desirably, in a range of approximately 50:1 to approximately 200:1. For instance, slurry uses ceria (CeO₂) as a polisher. To increase the etch ratio, an organic polymer, e.g. COₓ, NHₓ, NOₓ, wherein the x is a positive integer, is added. Also, pH is maintained at approximately 6 to approximately 8, and a dilution ratio of the polisher to deionized water (DIW) ranges from approximately 1:10 to approximately 1:100. The polisher has two kinds of particles having sizes of approximately 50 nm and approximately 200 nm, respectively.

During the etch-back process, the etched hard mask layer 103A is used as an etch barrier layer. Specifically, during the etch-back process, when the insulation layer 105 includes an oxide layer and the hard mask layer 103 includes a nitride layer, an etch ratio of the oxide layer to the nitride layer is more than approximately 50:1 and, desirably, in a range of approximately 50:1 to approximately 200:1. For instance, an etch gas includes a fluorocarbon compound such as tetrafluoromethane (CF₄), fluoroform (CHF₃), hexafluoroethane (C₂F₆), or octafluoropropane (C₃F₈). Desirably, a gas mixture of CH₃, C₄F₈, and CO may be used. Through the planarization process, a first insulation pattern 105A filling the trench 104 is formed.

Referring to FIG. 1E, the etched hard mask layer 103A is removed. The removal process is a wet etch process. For instance, when the hard mask layer 103 includes a nitride layer, the wet etch process is performed using a phosphoric acid (H₃PO₄) solution.

A cleaning process can be performed to remove unnecessary substances. The cleaning process uses a buffered HF (BHF), diluted HF, or buffered oxide etchant (BOE) solution. During the cleaning process, a portion of the first insulation pattern 105A can be etched so that a partially etched insulation layer, i.e. a second insulation pattern 105B, is formed.

Referring to FIG. 1F, the second insulation pattern 105B shown in FIG. 1E is etched and then planarized to form a third insulation pattern 105C. The planarization process is performed under a condition that an etch ratio of the insulation layer 105 and the first conductive layer 102 is more than approximately 2:1, and, desirably, in a range of approximately 2:1 to approximately 20:1. Thus, loss of the etched first conductive layer 102A is minimized while the third insulation pattern 105C is formed to have a regular height in an entire wafer region including the cell region.

For instance, when the insulation layer 105 includes an oxide layer and the first conductive layer 102 includes a polycrystalline silicon layer, the slurry uses the CeO₂ as a polisher. The pH is maintained at approximately 6 to approximately 8. Also, a dilution ratio of the polisher and the DIW ranges from approximately 1:10 to approximately 1:100. The relationship between the dilution ratio and the polish ratio is shown in Table 2. The polisher has two kinds of particles having sizes approximately 50 nm and approximately 200 nm, respectively.

TABLE 2

| | Polish ratio | | |
|---|---|---|---|
| | Polycrystalline | | |
| | silicon | Oxide layer | Oxide layer |
| Dilution ratio | layer:Nitride | (HDP):Polycrystalline | (HDP):Nitride |
| (Polisher:DIW) | layer | silicon layer | layer |
| 1:50 | 0.79:1 | 4.57:1 | 3.62:1 |
| 1:40 | 0.82:1 | 4.38:1 | 3.61:1 |
| 1:30 | 0.91:1 | 4.02:1 | 3.69:1 |

As shown in Table 2, the polish ratio of the polycrystalline silicon layer and the oxide layer increases as the dilution ratio of the polisher and the DIW increases.

Loss of the polycrystalline silicon layer is minimized by increasing the polish ratio of the polycrystalline silicon layer and the oxide layer. A dishing phenomenon partially occurring due to differences of pattern densities and widths can be prevented by adding an organic polymer, e.g., Coₓ, NHₓ, and NOₓ, wherein x is a positive integer. The dishing phenomenon causes a polish target layer in a certain region to be hollowed due to differences of the pattern densities and widths, thereby forming a dish-shape. The dishing phenomenon occurs not only in a device isolation layer at a border of the cell region and the peripheral region, the peripheral region having a relatively great width, but also in a device isolation layer in the cell region during the CMP process. The dishing effect decreases as the polish ratio increases. Thus, to increase the polish ratio, an organic polymer is added to the slurry.

Sequentially, a cleaning process can be performed after the polish process, i.e., the CMP process, to remove alien substances such as particles remaining after the CMP process. The cleaning process uses a BHF, a DHF, or a BOE solution. The cleaning process is performed to secure a uniform height of the third insulation pattern 105C.

Referring to FIG. 1G, the third insulation pattern 105C is recessed to a certain depth. Hereinafter, the recessed third insulation pattern 105C is referred to as a fourth insulation pattern 105D. To selectively etch the cell region for forming the memory cell, a wet or a dry etch process is performed using a photoresist pattern as an etch mask. The photoresist pattern is opened in the cell region but not in the peripheral region. Thus, a distance between an upper surface of the substrate pattern 100A, i.e., an active region, and an upper surface of the fourth insulation pattern 105D ranges from approximately 350 Å to approximately 400 Å.

Referring to FIG. 1H, a dielectric layer 106 is formed along the upper surface of the fourth insulation pattern 105D and the etched first conductive layer 102A. The dielectric layer 106 is formed to have a stack structure of oxide-nitride-oxide layers. In another embodiment, the dielectric layer 106 may include a metal oxide material having a permittivity greater than that of the SiON layer, for example, 3.9. The metal oxide material may include an Al₂0₃ layer, a ZrO₂ layer, a HfO₂ layer, a combination thereof or a stack structure thereof.

A second conductive layer 107 for a control gate is formed over the dielectric layer 106. The second conductive layer 107 may include conductive material. Desirably, the second conductive layer 107 includes the same material as the first conductive layer 102.

A metal nitride layer, a metal silicide layer, a stack structure thereof, or a hard mask can be additionally formed over the second conductive layer 107. For instance, the metal nitride layer is made of tungsten nitride (WN) and the metal silicide layer is made of tungsten silicide.

Hereinafter, advantages of the present invention are described. Firstly, in accordance with the present invention, when polishing an insulation layer for device isolation using a first conductive layer for a floating gate as a polish stop layer, a slurry including diluted with DIW is used. Thus, a polish ratio of the first conductive layer and the insulation layer is maximized and a height of the isolation layer is secured. As a result, it is possible to minimize loss of the first conductive layer and to secure a uniform thickness of the first conductive layer.

Secondly, in accordance with the present invention, when polishing the insulation layer for device isolation using the first conductive layer for a floating gate as a polish stop layer, a slurry including an organic polymer is used. Thus, a polish ratio of the first conductive layer and the insulation layer is maximized and a height of the isolation layer is secured. As a result, loss of the first conductive layer is minimized and a uniform thickness of the first conductive layer is secured.

Lastly, in accordance with the present invention, a polish ratio of the first conductive layer and the insulation layer increases to prevent a dishing phenomenon from occurring on the insulation layer. Thus, a height of the insulation layer is maintained at substantially the same as a height of the first conductive layer. That is, it is possible to secure a uniform thickness of the insulation layer. Since a depth recessed when adjusting a subsequent EFH is uniform, it is possible to secure uniformity of the EFH in an entire wafer region.

While the present invention has been described with respect to specific embodiments, the above embodiments of the present invention are illustrative and not limitative. In the present invention, a method employing the ASA-STI process is described. However, this invention can be applied to other methods employing the SA-STI process. Furthermore, this invention can be applied to other methods for fabricating a NAND flash memory device including a recess process for adjusting EHF. It will be apparent to those skilled in the art that various changes and modifications may be made without departing from the spirit and scope of the invention as defined in the following claims.

What is claimed is:

1. A method for forming a nonvolatile memory device, the method comprising:
forming a tunnel insulation layer and a first conductive layer over a substrate;
forming a trench by partially etching the first conductive layer, the tunnel insulation layer and the substrate, thereby forming a resultant structure;
forming an insulation layer over the resultant structure to fill the trench; and
polishing the insulation layer using a slurry including a polisher diluted with deionized water to expose the first conductive layer.

2. The method of claim 1, wherein a dilution ratio of the polisher and the deionized water is approximately 1:10 to approximately 1:100.

3. The method of claim 1, wherein the slurry further includes an organic polymer.

4. The method of claim 3, wherein the organic polymer is one of COₓ, NHₓ, and NOₓ, x being a positive integer.

5. The method of claim 1, wherein the slurry has a pH ranging from approximately 6 to approximately 8.

6. The method of claim 1, wherein the slurry uses a ceria (CeO₂)-based polisher.

7. The method of claim 1, wherein the first conductive layer includes a polycrystalline silicon layer.

8. The method of claim 7, wherein the insulation layer includes an oxide layer.

9. The method of claim 1, further comprising forming a hard mask over the first conductive layer after forming the first conductive layer.

10. The method of claim 9, further comprising forming a buffer layer over the first conductive layer before forming the hard mask.

11. The method of claim 10, wherein the hard mask includes a nitride layer and the buffer layer includes an oxide layer.

12. The method of claim 9, further comprising polishing the insulation layer by performing a polish process to expose the hard mask.

13. The method of claim 12, wherein the polish process uses a slurry including a polisher diluted with deionized water.

14. The method of claim 13, wherein the slurry further includes an organic polymer.

15. The method of claim 14, wherein the organic polymer included in the slurry used for the polish process is one of COₓ, NHₓ, and NOₓ, x being a positive integer.

16. The method of claim 12, wherein the polish process uses a slurry including an organic polymer.

17. The method of claim 16, wherein the organic polymer included in the slurry used for the polish process is one of COₓ, NHₓ, and NOₓ, x being a positive integer.

18. The method of claim 12, wherein the slurry used for the polish process uses a CeO₂-based polisher.

19. The method of claim 9, further comprising etching the insulation layer using the hard mask as an etch barrier layer after forming the insulation layer.

20. The method of claim 19, wherein etching the insulation layer is performed by an etch-back process.

21. The method of claim 12, further comprising, after polishing the insulation layer by performing the polishing process to expose the hard mask, removing the hard mask.

22. The method of claim 21, wherein the hard mask is removed using a phosphoric acid (H₃PO₄) solution.

23. The method of claim 1, further comprising, after polishing the insulation layer:
recessing the insulation layer;
forming a dielectric layer over an upper surface of the recessed insulation layer and the exposed employed first conductive layer; and
forming a second conductive layer over the dielectric layer.

24. A method for fabricating a nonvolatile memory device, the method comprising:
forming a tunnel insulation layer and a first conductive layer over a substrate;
forming a trench by partially etching the first conductive layer, the tunnel insulation layer, and the substrate, thereby forming a resultant structure;
forming an insulation layer over the resultant structure to fill the trench; and
polishing the insulation layer using a slurry including an organic polymer to expose the first conductive layer.

25. The method of claim 24, wherein the organic polymer is one of COₓ, NHₓ, and NOₓ, x being a positive integer.

26. The method of claim 24, wherein the slurry has a pH ranging from approximately 6 to approximately 8.

27. The method of claim 24, wherein the slurry uses a ceria (CeO₂)-based polisher.

28. The method of claim 24, wherein the first conductive layer includes a polycrystalline silicon layer.

29. The method of claim 28, wherein the insulation layer includes an oxide layer.

30. The method of claim 24, further comprising forming a hard mask over the first conductive layer after forming the first conductive layer.

31. The method of claim 30, further comprising forming a buffer layer over the first conductive layer before forming the hard mask.

32. The method of claim 31, wherein the hard mask includes a nitride layer and the buffer layer includes an oxide layer.

33. The method of claim 30, further comprising polishing the insulation layer by performing a polish process to expose the hard mask.

34. The method of claim 33, wherein the polish process uses a slurry including a polisher diluted with deionized water.

35. The method of claim 34, wherein the slurry further includes an organic polymer.

36. The method of claim 35, wherein the organic polymer included in the slurry used for the polish process is one of COₓ, NHₓ, and NOₓ, x being a positive integer.

37. The method of claim 33, wherein the polish process uses a slurry including an organic polymer.

38. The method of claim 37, wherein the organic polymer included in the slurry used for the polish process is one of COₓ, NHₓ, and NOₓ, x being a positive integer.

39. The method of claim 33, wherein the slurry used for the polish process uses a CeO₂-based polisher.

40. The method of claim 30, further comprising etching the insulation layer using the hard mask as an etch barrier layer after forming the insulation layer.

41. The method of claim 40, wherein etching the insulation layer is performed by an etch-back process.

42. The method of claim 33, further comprising, after polishing the insulation layer by performing the polishing process to expose the hard mask, removing the hard mask.

43. The method of claim 42, wherein the hard mask is removed using a phosphoric acid (H₃PO₄) solution.

44. The method of claim 24, further comprising, after polishing the insulation layer:
recessing the insulation layer;
forming a dielectric layer over an upper surface of the recessed insulation layer and the exposed employed first conductive layer; and
forming a second conductive layer over the dielectric layer.
